(19) United States
(12) Patent Application Publication
(10) Pub. No.: US 2010/0013388 A1
(43) Pub. Date: Jan. 21, 2010

(54) Electroluminescent Plate, Product Containing the Same, and Preparing Method Thereof

(76) Inventors: Jianghui Li, Shenzhen (CN); Hongzhen Zhao, Shenzhen (CN); Mingzhu Chang, Shenzhen (CN); Jiaxin Zhang, Shenzhen (CN)

Correspondence Address: MORGAN, LEWIS & BOCKIUS, LLP. (PA), 2 PALO ALTO SQUARE, 3000 EL CAMINO REAL, SUITE 700, PALO ALTO, CA, 94306, US

(21) Appl. No.: 12/500,571

(22) Filed: Jul. 9, 2009

(30) Foreign Application Priority Data
Jul. 18, 2008 (CN) 200810068553.5

(51) Int. Cl. H01L 23/02; B32B 37/12

(52) U.S. Cl. 313/506; 264/134

(57) ABSTRACT

A case product comprises an EL plate and a plastic shell, wherein the EL plate comprising a substrate film, a transparent electrode layer, a light-emitting layer, an insulating layer, a back electrode layer, and an adhesive layer, wherein the substrate film, the transparent electrode layer, the light-emitting layer, the insulating layer, the back electrode layer, the protective layer and the adhesive layer are configured to be positioned next to each other in a predefined order. And a method of preparing a case product comprises: coating a substrate film with a transparent electrode layer, a light-emitting layer, an insulating layer, a back electrode layer, a protective layer and an adhesive layer; shaping the substrate film in a high-pressure mold; cutting the substrate film in a cutting mold to form an EL plate; molding the EL plate in an injection mold, and integrating the EL plate with a plastic shell.

### CROSS-REFERENCE TO RELATED APPLICATION

The present application claims priority to Chinese Patent Application No. 200810068553.5, filed on Jul. 18, 2008, the disclosure of which is hereby incorporated by reference in its entirety.

### BACKGROUND OF THE INVENTION

1. Field of the Invention

The present invention relates to an electroluminescent plate (EL plate), a case product comprising an EL plate, and methods for preparing the EL plate and the case product.

2. Background of the Related Art

At present, products with light-emitting decoration on the surface mainly have two categories: a product with a light-emitting sheet attached to it using adhesive materials; and a product having a guiding plate with LED lamps attached to its case. The first one is more popular in the aircraft; and the second one is more popular in other high-tech areas due to its advantages such as small size, light weight, less heat generation, less electric consumption, no flash, uniform luminescence, large area of luminescence and so on. Thus, the EL plate is used as back light in many popular consumer electronics such as mobile telephone, radio beeper, cordless phone, PDA, remote controller and so on.

An EL plate includes a non-conductive substrate coated with light-emitting material and the EL plate is configured to be sandwiched between two electrodes and driven to emit light by an EL plate driver. Conventionally, an EL plate is used as a decoration attached to the outer surface of a product using glue or double-side glue tape. The appearance of the product is not appealing. And the influence from the oxygen and moisture when the EL plate is exposed in the air also reduces the stability and the life of the product.

### SUMMARY OF THE INVENTION

One embodiment of the present invention is an EL plate that comprises a substrate film, a transparent electrode layer, a light-emitting layer, an insulating layer, a back electrode layer, and an adhesive layer. Said transparent electrode layer is disposed on said substrate film; said light-emitting layer is disposed on said transparent electrode layer; said insulating layer is disposed on said light-emitting layer; said back electrode layer is disposed on said insulating layer; and said adhesive layer is disposed on said back electrode layer

Another embodiment of the present invention is a method of preparing an EL plate, comprises:
a. coating the surface of a prepared substrate film with conducting polymer to form a transparent electrode layer; coating the surface of the transparent electrode layer with light-emitting ink to form a light-emitting layer; coating the surface of the light-emitting layer with insulating ink to form an insulating layer; coating the surface of the insulating layer with ink mixed of polyester and silver powder to form a back electrode layer; coating the surface of the back electrode layer with ink mixed with MgSiO3 and resin to form a protective layer; coating the surface of the protective layer with adhesive to form an adhesive layer;
b. shaping the prepared substrate film coated with the transparent electrode layer, the light-emitting layer, the insulating layer, the back electrode layer, the protective layer and the adhesive layer in a high-pressure mold; and
c. cutting the prepared substrate film coated with the transparent electrode layer, the light-emitting layer, the insulating layer, the back electrode layer, the protective layer and the adhesive layer in a cutting mold to form an EL plate with a predefined size and shape.

Another embodiment of the present invention is a case product comprising an EL plate and a plastic shell, wherein the EL plate comprises a substrate film, a transparent electrode layer, a light-emitting layer, an insulating layer, a back electrode layer, a protective layer and an adhesive layer, wherein the substrate film, the transparent electrode layer, the light-emitting layer, the insulating layer, the back electrode layer, the protective layer and the adhesive layer are configured to be positioned next to each other in a predefined order.

Another embodiment of the present invention is a method of preparing a case product comprises the steps of: preparing an EL plate, and injection molding the EL plate with a plastic shell:
a. coating the surface of a prepared substrate film with conducting polymer to form a transparent electrode layer; coating the surface of the transparent electrode layer with light-emitting ink to form a light-emitting layer; coating the surface of the light-emitting layer with insulating ink to form an insulating layer; coating the surface of the insulating layer with ink mixed of polyester and silver powder to form a back electrode layer; coating the surface of the back electrode layer with ink mixed of MgSiO3 and resin to form a protective layer; coating the surface of the protective layer with sticky ink to form an adhesive layer;
b. shaping the prepared substrate film coated with the transparent electrode layer, the light-emitting layer, the insulating layer, the back electrode layer, the protective layer and the adhesive layer in a high-pressure mold;
c. cutting the prepared substrate film coated with the transparent electrode layer, the light-emitting layer, the insulating layer, the back electrode layer, the protective layer and the adhesive layer in a cutting mold to form an EL plate with a predefined size and shape; and
d. molding the EL plate in an injection mold, and integrating the EL plate with a plastic shell.

### BRIEF DESCRIPTION OF THE DRAWINGS

FIG. 1 is a cross sectional view showing the structure of the EL plate 1 comprising: substrate film 10, transparent electrode layer 11, light-emitting layer 12, insulating layer 13, back electrode layer 14, protective layer 15 and adhesive layer 16, wherein the substrate film and all other layers are configured to be positioned next to each other in a predefined order.

FIG. 2 is a cross sectional view of a high-pressure mold 2 and the EL plate 1 when being shaped by the high-pressure mold 2. The high-pressure mold 2 mainly comprises an upper template 20, a lower template 22, a pressure plate 24 and a core mold 222.

FIG. 3 is a cross sectional view of a cutting mold 3 and the EL plate 1 when being cut by the cutting mold 3. The cutting mold 3 mainly comprises an upper template 30, a pressure plate 32, an upper cut 34 and a lower cut 36.

FIG. 4 is a cross sectional view of an injection mold cavity 40 and the EL plate 1 subject to injection molding. The EL plate surface without adhesive layer 16 is set to attach to the surface of the injection mold cavity 40. By the adhesive layer 16, the EL plate 1 is integrated with the outer surface of the plastic shell 44 during injection molding.

### DETAILED DESCRIPTION OF THE EMBODIMENTS

The present invention provides an EL plate, a case product with EL plate, and the methods of preparing the EL plate and the case product.

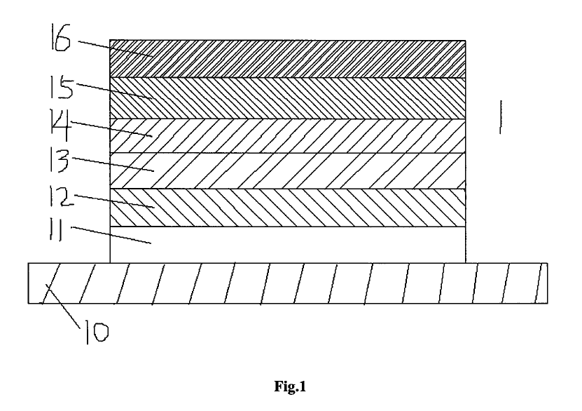

In one embodiment, as shown in FIG. 1, an EL plate 1 comprises: a substrate film 10, a transparent electrode layer 11, a light-emitting layer 12, an insulating layer 13, a back electrode layer 14, a protective layer 15 and an adhesive layer 16.

Wherein, said substrate film 10 is a plastic film with the good character of thermoplastic deformation, such as Polyethylene terephthalate (PET) or polycarbonate (PC). The transparent electrode layer 11 is disposed on top of the substrate film, and is made of an electrode polymer which can be polyethylenedioxythiophene (PEDT). The light-emitting layer 12 is disposed on top of the transparent electrode layer 11. To guide light, the light-emitting layer 12 is made of light-emitting ink based on ZnS, and mixed with other light-emitting dye according to the color requirement. For example, the ink is dark blue when mixed with Cu and Al. The insulating layer 13 is disposed on top of the light-emitting layer 12, and is made of insulating ink. As an insulating electrolyte, the insulating ink is a composite of BaTiO3 and resin; the insulating layer 13 is used to avoid the current in the electric field. The back electrode layer 14 is disposed on top of the insulating layer 13 used for conduction, and is made of ink mixed with silver powder and polyester, and mixed with the powder of carbon, silver and crop. The protective layer 15 is disposed on top of the back electrode layer 14, and is made of ink mixed with MgSiO3 and resin; and it is non-conducting and insulates the EL plate from moisture and oxygen in the air. The adhesive layer 16 is disposed on top of the protective layer 15, and is made of adhesive material with high temperature resistance and low thermal conductivity. Accordingly, the structure of the EL plate detailed above can be shaped and injection molded at high temperature, and it enhances the connection between the EL plate and the plastic shell.

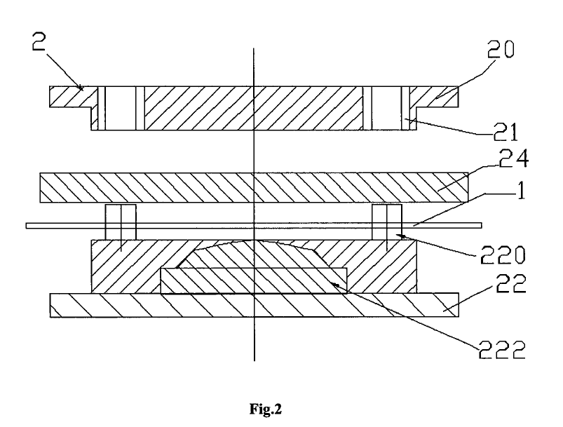

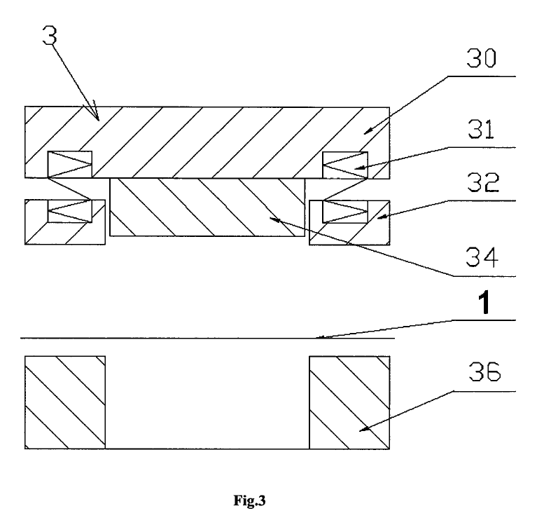

In another embodiment, from FIGS. 1 to 3, a method of preparing an EL plate comprises a step of preparing an EL plate: first, preparing a substrate film 10; second, coating the surface of a prepared substrate film 10 with a conducting polymer( may be PEDT) to form a transparent electrode layer 11 with printing or other known ways; third, coating the surface of the transparent electrode layer 11 with a light-emitting ink to form a light-emitting layer 12; fourth, coating the surface of the light-emitting layer 12 with an insulating ink to form an insulating layer 13; fifth, coating the surface of the insulating layer 13 with ink mixed with polyester and silver powder to form a back electrode layer 14; sixth, coating the surface of the back electrode layer 14 with ink mixed with MgSiO3 and resin to form a protective layer 15; seventh, coating the surface of the protective layer 15 with adhesive to form an adhesive layer 16. Wherein, to meet the thickness requirement of a product, such as a telephone, the thickness of each layer is set as: 100˜300 μm for substrate film 10; 50˜100 nm for transparent electrode layer 11; about 38 nm for light-emitting layer 12; about 30 nm for insulating layer 13; about 10 nm for back electrode layer 14; about 20 nm for protective layer; and about 40 nm for adhesive layer 16.

The process of shaping the EL plate shapes the prepared substrate film 10 coated with the transparent electrode layer 11, the light-emitting layer 12, the insulating layer 13, the back electrode layer 14, the protective layer 15 and the adhesive layer 16 in a high-pressure mold 2. The high-pressure mold 2 comprises an upper template 20, a lower template 22, a pressure plate 24 and a core mold 222. The upper template 20 is fixed by a guide sleeve 21; the pressure plate 24 is configured to be in the middle of the high-pressure mold 2; and the core mold 222 is configured to be on the lower template 22 which is fixed by fixing posts 220 and used for shaping the EL plate 1; and there are several discharge holes under the core mold 222 to exhaust the gas under the EL plate 1 during molding.

The process of molding comprises the steps of: fixing the EL plate 1 on the core mold 222 in the lower template 22 with fixing posts 220; pressing and fixing the EL plate 1 with the pressure plate 24; then closing the high-pressure mold 2, and pressing the upper template 20 and the pressure plate 24 on the lower template 22 and the EL plate 1; preheating the EL plate 1 and the core mold 222 for 30 to 60 seconds, so that the EL plate 1 can be shaped easily; injecting high pressure gas into the high-pressure mold 2, clinging the EL plate 1 on the core mold 222; shaping the EL plate 1 under the same pressure for about 30 seconds.

The cutting mold 3 comprises an upper template 30, a pressure plate 32, an upper cut 34 and a lower cut 36. The upper cut 34 is fixed on the upper template 30 and the pressure plate 32 connects to the upper template 30 with spring 31.

The process of cutting comprises the steps of: setting the shaped EL plate 1 on the lower cut 36; moving the upper template 30 towards the lower template 36 until the pressure plate 32 connects to the EL plate 1; then matching the upper cut 34 with the lower cut 36. Thus, the superfluous parts of the EL plate 1 can be cut off with the cutting mold.

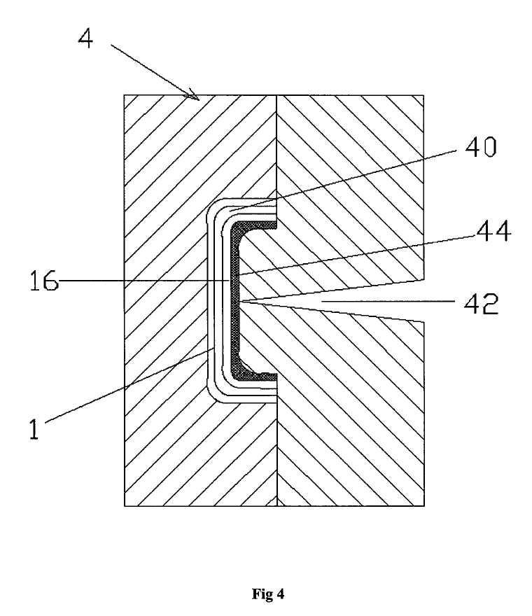

The present invention further provides a case product comprises an EL plate 1 and a plastic shell 44, as shown in FIGS. 1 to 4.

Further, in another embodiment, a method of preparing a case product with EL plate comprises the steps of: preparing an EL plate as aforementioned, and injection molding, which are detailed herewith: setting the cut EL plate in a mold cavity 40, and configuring the surface of the EL plate without adhesive layer 16 to face the surface of the mold cavity 40; then injecting plastic from a injection port 42 which connects to the mold cavity 40; by the adhesive layer 16, integrating the EL plate 1 with the outer surface of the plastic shell 44 during injection molding. Thus, a case product such as a telephone case is formed.

During the process of shaping and injection molding under high temperature and high pressure, because the adhesive layer 16 on the EL plate 1 has low thermal conductivity, the EL plate 1 will not be destroyed by the high temperature, and the adhesive force between the EL plate 1 and the plastic shell 44 can be improved. Furthermore, the protective layer 15 is insulating, thus protecting the transparent electrode layer 11, the light-emitting layer 12, the insulating layer 13 and the back electrode layer 14 effectively, and then the EL plate 1 can be integrated with the plastic shell 44 effectively.

As detailed in the invention, after shaping and cutting, the EL plate can be integrated with the plastic shell during injection molding; and with the protection of the plastic shell, the EL plate can be insulated well from oxygen and moisture in the air, which improves the stability and prolongs the life of the EL plate.

Many modifications and other embodiments of the present invention will come to mind to one skilled in the art to which the present invention pertains having the benefit of the teachings presented in the foregoing description. It will be apparent to those skilled in the art that variations and modifications of the present invention can be made without departing from the scope or spirit of the present invention. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An electroluminescent plate (EL plate) comprises: a substrate film, a transparent electrode layer, a light-emitting layer, an insulating layer, a back electrode layer, and an adhesive layer, wherein
said transparent electrode layer is disposed on said substrate film; said light-emitting layer is disposed on said transparent electrode layer; said insulating layer is disposed on said light-emitting layer; said back electrode layer is disposed on said insulating layer; and said adhesive layer is disposed on said back electrode layer.

2. An EL plate according to claim 1, wherein said transparent electrode layer is made of polyethylenedioxythiophene (PEDT) deposited on top of the substrate film.

3. An EL plate according to claim 1, wherein said light-emitting layer is made of light-emitting ink including ZnS deposited on top of the transparent electrode layer.

4. An EL plate according to claim 1, wherein said insulating layer is made of insulating ink composite of BaTiO3 and resin deposited on top of the light-emitting layer.

5. An EL plate according to claim 1, wherein said back electrode layer is made of ink comprising of polyester and silver powder deposited on top of the insulating layer.

6. An EL plate according to claim 1 further comprises a protective layer, wherein the protective layer is made of ink including MgSiO3 and resin deposited on top of the back electrode layer.

7. An EL plate according to claim 1, wherein said adhesive layer is made of adhesive deposited on top of the protective layer.

8. A method of preparing an EL plate comprises the steps of:
a. coating the surface of a prepared substrate film with conducting polymer to form a transparent electrode layer; coating the surface of the transparent electrode layer with light-emitting ink to form a light-emitting layer; coating the surface of the light-emitting layer with insulating ink to form an insulating layer; coating the surface of the insulating layer with ink mixed of polyester and silver powder to form a back electrode layer; coating the surface of the back electrode layer with ink mixed of MgSiO3 and resin to form a protective layer; coating the surface of the protective layer with adhesive to form an adhesive layer;
b. shaping the prepared substrate film coated with the transparent electrode layer, the light-emitting layer, the insulating layer, the back electrode layer, the protective layer and the adhesive layer in a high-pressure mold; and
c. cutting the prepared substrate film coated with the transparent electrode layer, the light-emitting layer, the insulating layer, the back electrode layer, the protective layer and the adhesive layer using a cutting mold to form an EL plate with a predefined size and shape.

9. A method of preparing an EL plate according to claim 8, wherein said high-pressure mold comprises an upper template, a lower template, a pressure plate and a core mold, wherein the pressure plate is configured to be in the middle of the high-pressure mold, and the core mold is configured to be on the lower template.

10. A method of preparing an EL plate according to claim 8, wherein the molding process comprises the steps of: fixing the EL plate on the lower template with a fixing post; closing the high-pressure mold, thus pressing the upper template and the pressure plate on the lower template with the EL plate; injecting high pressure gas into the high-pressure mold after preheating the EL plate and the core mold, and clinging the EL plate on the core mold; shaping the EL plate under the same pressure.

11. A method of preparing an EL plate according to claim 8, wherein said cutting mold comprises an upper template, a pressure plate, an upper cut and a lower cut, wherein the upper cut is fixed on the upper template, and the pressure plate connects to the upper template.

12. A method of preparing an EL plate according to claim 11, wherein the cutting process comprises the steps of: setting the EL plate on the lower cut; moving the upper template towards the lower template until the pressure plate connects to the EL plate; then matching the upper cut with the lower cut; cutting off superfluous parts of the EL plate with the cutting mold.

13. A case product comprises an EL plate and a plastic shell, wherein the EL plate comprises a substrate film, a transparent electrode layer, a light-emitting layer, an insulating layer, a back electrode layer, a protective layer and an adhesive layer, wherein the substrate film, the transparent electrode layer, the light-emitting layer, the insulating layer, the back electrode layer, the protective layer and the adhesive layer are configured to be positioned next to each other in a predefined order.

14. A case product according to claim 13, wherein the EL plate is integrated with the plastic shell by the adhesive layer.

15. A method of preparing an EL plate according to claim 8, further comprising the step of:
molding the EL plate in an injection mold, and integrating the EL plate with a plastic shell.

16. A method of preparing a EL plate according to claim 15, wherein the surface of the EL plate without adhesive layer is configured to face a mold cavity; by the adhesive layer, the EL plate is integrated with the outer surface of the plastic shell during injection molding.
